(19) United States
(12) Patent Application Publication
(10) Pub. No.: US 2016/0143178 A1
(43) Pub. Date: May 19, 2016

(54) Baffle and Reinforcement System

(71) Applicant: Dell Products L.P., Round Rock, TX (US)

(72) Inventors: Yen-Lin Wang, Taipei (TW); Hsu-Chu Wang, Taipei (TW); Kuang Hsi Lin, TaouYuan County (TW)

(21) Appl. No.: 14/604,326

(22) Filed: Jan. 23, 2015

Related U.S. Application Data
(60) Provisional application No. 62/081,901, filed on Nov. 19, 2014.

(51) Int. Cl. H05K 7/20

(52) U.S. Cl. CPC H05K 7/20

(57) ABSTRACT

In one embodiment, a system comprises a bar and a baffle. The bar is connected to a frame through a plurality of holes in a board. The baffle is connected to the bar and is configured to direct air to components on the board. One or more fasteners may be used to connect the bar and the baffle.

### RELATED APPLICATION

This application claims the benefit under 35 U.S.C. §119(e), of U.S. Provisional Patent Application No. 62/081901, filed Nov. 19, 2014, which is incorporated by reference herein.

### TECHNICAL FIELD

This disclosure relates generally to computer components and more particularly to a baffle and reinforcement system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. For example, an information handling system may be a tablet computer or mobile device (e.g., personal digital assistant (PDA) or smart phone) configured to transmit data on a wireless communications network. Information handling systems may include a variety of hardware and software components that may be configured to process, store, and communicate information and may include one or more computer systems, data storage systems, and networking systems.

Certain information handling systems can be implemented within a modular chassis. In such implementations, a modular chassis may be configured to receive a plurality of individual frames. Each frame may be adapted to removeably attach to the chassis via an appropriate bay of the chassis (e.g., by sliding the frame in or out of the bay.) Each frame may include one or more information handling systems, which includes a number of components. As the number of components in the information handling system increases, space within each frame becomes valuable.

### SUMMARY

In one embodiment, a system comprises a bar and a baffle. The bar is connected to a frame through a plurality of holes in a board. The baffle is connected to the bar and is configured to direct air to components on the board.

In one embodiment, a method comprises connecting a baffle to a bar. The baffle may be configured to direct air to components on a board.

Certain embodiments of the present disclosure may provide one or more technical advantages. For example, one advantage includes the bar and the baffle providing additional stiffness and rigidness to the frame. This allows the frame to support the weight of components like processor heatsinks, memory modules, and boards. This also prevents frame deformation and/or screws loosening. The added strength improves frame bottom flatness, allowing the frame to fit in a bay of a chassis that may contain little to no extra room.

Another example of a technical advantage is allowing air flow adjustment for cooling. The baffle functions as an air flow guide, with the opening vent adjusting the air flow for downstream component cooling, particularly the processors and memory modules.

Another example of a technical advantage is providing tool-less access to the memory modules. Because of the space constraints on the frame, there is limited room to include a baffle. In some embodiments, the baffle may be removed from the frame without the use of tools, thus allowing access to the memory modules without sacrificing the added strength to the frame and the component cooling provided by the baffle.

Other technical advantages of the present disclosure will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

Reference is now made to the following description taken in conjunction with the accompanying drawings, wherein like reference numbers represent like parts.

FIG. 1A is an exploded view of an information handling system and its components, including a baffle and a bar.

FIG. 1B is an assembled view of the information handling system of FIG. 1A.

FIGS. 2A and 2B illustrate examples of a bar.

FIGS. 3A and 3B illustrate examples of a baffle.

FIG. 4 illustrates an example of connecting a bar and a baffle to a frame.

FIG. 5 is a cross-sectional view of an example of the information handling system with a baffle and a bar.

FIG. 6 is a cross-sectional view of an example of an information handling system with a bar and with a removed baffle.

FIG. 7 is a flowchart of an example of connecting a baffle and a bar to an information handling system.

### DETAILED DESCRIPTION

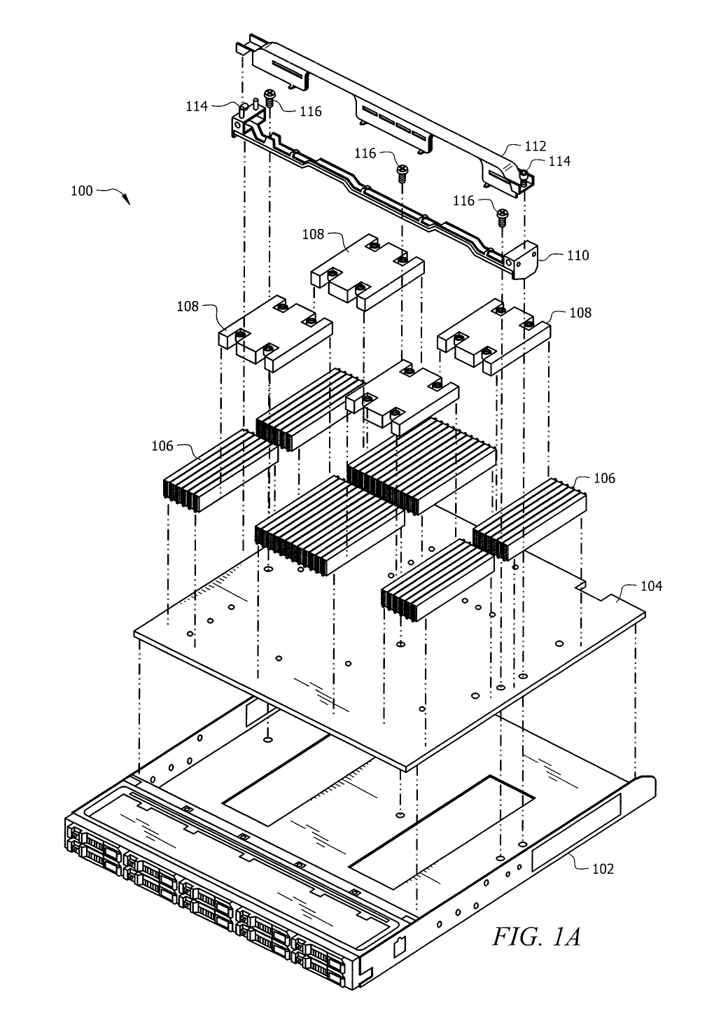

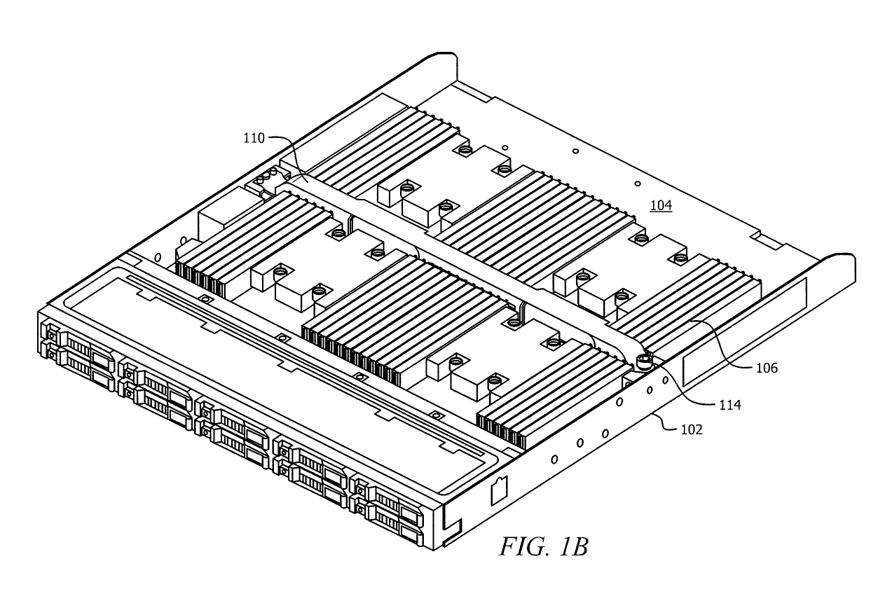

FIG. 1A is an exploded view of information handling system 100 and its components, including baffle 112 and bar 110, and FIG. 1B is an assembled view of information handling system 100 of FIG. 1A. In some embodiments, components of information handling system 100 may include frame 102, board 104, memory modules 106, processor heatsinks 108, bar 110, baffle 112, and one or more fasteners 114. Board 104 may be housed within and connected to frame 102. Included on board 104 may be one or more components, such as memory modules 106 and processor heatsinks 108. Also, bar 110 may be connected to frame 102 through board 104. Baffle 112 may be connected to bar 110 using one or more fasteners 114. In some embodiments, connecting bar 110 to frame 102 provides reinforcement to frame 102 by assisting frame 102 in supporting the weight of board 104 and its components (e.g., memory modules 106 and processor heatsinks 108). This may reduce or stop deformation of frame 102. Connecting baffle 112 to bar 110 can provide additional stiffness to frame 102 and can allow air flow adjustment to provide cooling for components of board 104 (e.g., processor heatsinks 108 and memory modules 106).

Information handling system 100, in some embodiments, may comprise any instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, information handling system 100 may be a personal computer, a PDA, a consumer electronic device, a network storage device, a server sled, a server node, or another suitable device and may vary in size, shape, performance, functionality, and price.

As shown in FIG. 1A, components of information handling system 100 may include, but are not limited to, frame 102, board 104, memory module 106, processor heatsink 108, bar 110, baffle 112, and fastener 114. Although FIG. 1A illustrates a certain number of each component in information handling system 100, it should be understood that information handling system 100 may comprise one or more of each component, and may comprise only some of the components while omitting others. In addition, information handling system 100 may comprise additional components not illustrated in FIG. 1A. For example, information handling system 100 may include one or more communications ports for communicating with external devices. Information handling system 100 may also include firmware for controlling and/or communicating with, for example, hard drives, network circuitry, memory devices, I/O devices, and other peripheral devices.

Frame 102, in some embodiments, may be a server sled, server module, server node, or any suitable structure capable of housing board 104. Frame 102 may be inserted into a modular chassis, which can be configured to receive multiple other frames 102. Each frame may be adapted to removeably couple to the chassis via an appropriate bay of the chassis (e.g., by sliding the frame in or out of the bay.) In some embodiments, frame 102 may include a base and one or more side walls to house board 104 and its components (e.g., processor heatsinks 108 and memory modules 106). Frame 102 may not include a cover (e.g., top portion) to enclose board 104. This lack of a top portion in frame 102 allows, for example, additional room for components in a high density environment (e.g., stacked height limitation in chassis).

Without a cover, the bays in the chassis require less room to house multiple frames 102, but without structural support from the cover, each frame may have a weaker structure more vulnerable to deformation. In some embodiments, frame 102 may be various widths (e.g., quarter width, half width, and full width), each width being a different size. Without structural support from bar 110 and baffle 112, the weight of the components may cause deformation in frame 102 (especially when frame 102 has a larger width), which may prevent frame 102 from being inserted into a bay of the chassis.

Board 104, in some embodiments, may be a circuit board, a mother board, or any suitable board configured to receive components in order to processes information. Board 104 may have a plurality of connectors to couple with processing components, such as processor 108, memory module 106, and any other necessary components. The components interact by communication through board 104 to process information. Board 104 may be connected to or housed within frame 102. In some embodiments, board 104 is connected to bar 110. Board 104 may comprise a plurality of holes to facilitate fasteners 114 and fasteners 116 connecting bar 110 to frame 102.

Memory modules 106 may, in various embodiments, be any system, device, or apparatus operable to retain and/or retrieve program instructions and/or data (e.g., computer-readable media). Memory modules 106 can include random access memory (RAM) modules, electrically erasable programmable read-only memory (EEPROM) modules, a PCMCIA card, flash memory modules, magnetic storage modules, opto-magnetic storage modules, and/or a suitable selection and/or array of volatile or non-volatile memory modules. Memory modules 106 may be situated on board 104 within frame 102.

Processor heatsinks 108, in some embodiments, may be any system, device, or apparatus operable to house and/or attach to a processor to absorb heat or provide cooling to the processor. This can help reduce the chances of or prevent processors on board 104 from overheating. Such processors may be one or more: microprocessors, microcontrollers, digital signal processors (DSP), application specific integrated circuits (ASIC), or another component comprising digital or analog circuitry configured to interpret and/or execute program instructions and/or process data. In some embodiments, processors may interpret and/or execute program instructions and/or process data stored locally (e.g., in memory modules 106). In the same or alternative embodiments, processors may interpret and/or execute program instructions and/or process data stored remotely. Processors and associated processor heatsinks 108 may be situated on board 104 within frame 102.

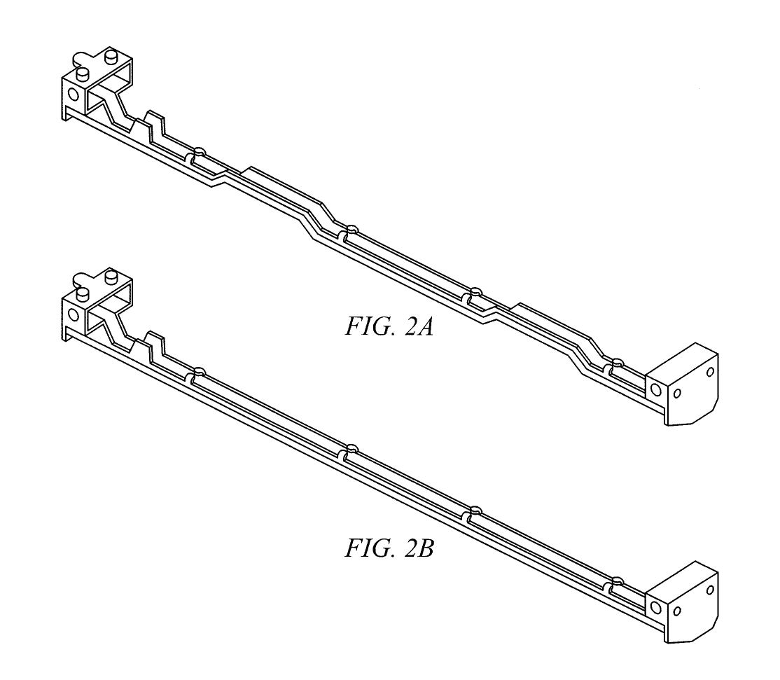

Bar 110, in some embodiments, may be a rigid bar, a stiff bar, or any suitable structure configured to provide strength to frame 102. In some embodiments, bar 110 may be connected in the middle of frame 102, as shown in FIGS. 1A and 1B. For example, this can provide strength to a part of frame 102 that may be vulnerable to deformation. In some embodiments, bar 110 may comprise a set of tabs to facilitate engagement with baffle 112. Bar 110 may be made out of any suitable material to provide additional strength to frame 102, such as metal or plastic. FIG. 2A and FIG. 2B illustrate alternative examples of bar 110. In some embodiments, bar 110 may include certain raised portions in order to make room for components on board 104. For example, by raising certain portions of bar 110, board 104 and its components do not need to be rearranged because the raised portions of bar 110 allow room for the components. An example of bar 110 with raised portions is shown in FIG. 2A. In some embodiments, bar 110 may be substantially straight (e.g., without any raised portions), allowing a greater amount of the bottom surface area of bar 104 (e.g., the majority of its bottom surface area) to make contact with board 104. An example of bar 110 that is substantially straight is shown in FIG. 2B. Bar 110 may be made of any material to provide additional strength to frame 102 to prevent deformation. For example, bar 110 may be made of metal or a strong plastic (e.g., nylon, PVC, or polycarboante). In some embodiments, bar 110 can be secured to frame 102 and board 104 using fasteners 116 that go through bar 110 in multiple places.

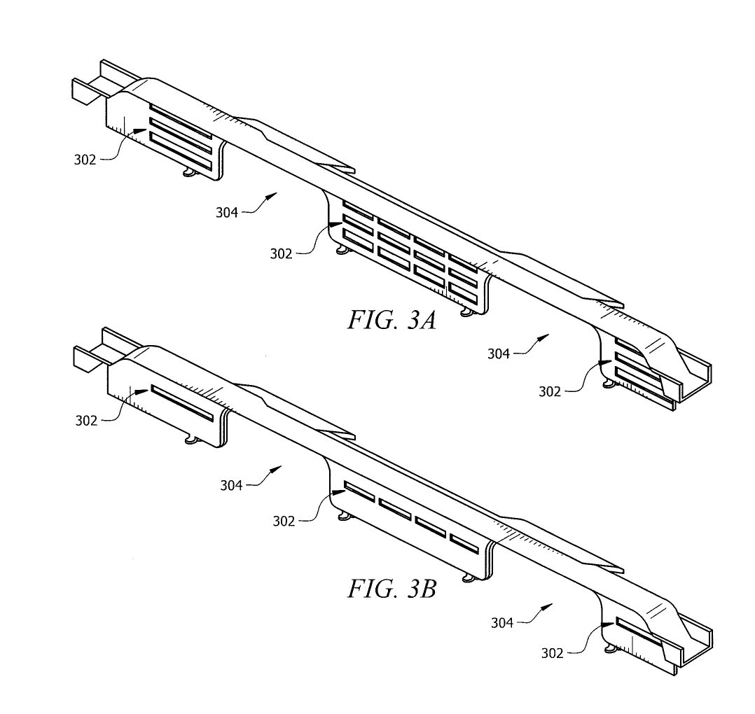

Baffle 112, in some embodiments, may be an air baffle or any device configured to direct air to components on board 104. Baffle 112 may comprise openings that facilitate directing air to components on board 104. In some embodiments, baffle 112 may comprise a first set of tabs to facilitate engagement with bar 110. Baffle 112 may also be connected to bar 110 using one or more fasteners 114 (e.g., thumb screws and/or hook and slot engagements). Baffle 112 may be made out of any material that can provide additional strength to frame 102, such as metal or strong plastic (e.g., nylon, PVC, or polycarbonate). Examples of baffle 112 are shown in FIG. 3A and FIG. 3B. As shown in FIG. 3A and FIG. 3B, baffle 112 may include any suitable number of openings. Baffle 112 may be made of any material to provide additional strength to frame 102 to prevent deformation. For example, baffle 112 may be made of metal or a strong plastic (e.g., nylon, PVC, or polycarbonate).

Fasteners 114, in some embodiments, may include screws, thumb screws, hook and slot features, additional tabs, bolts, buckles, solder, buttons or any component that further engages the connection between components in information handling system 100 (e.g., between bar 110 and baffle 112, between bar 110 and frame 102, between board 104 and frame 102). For example, board 104 may be connected to frame 102 using screws, bolts, buckles, solder, buttons, or any suitable fastener 114 to connect these components. As another example, baffle 112 may be connected to bar 110 using protruding tabs, hook and slot features, thumb screws, or any suitable fastener 114 to connect these components. In connecting any components, a combination of different types of fasteners 114 can be used to secure the connection. Fasteners 116 can be implemented using any techniques discussed above with respect to fasteners 114. In some embodiments, bar 110 may be connected to frame 102 using screws, bolts, solder, or any suitable fastener 116 along the length of bar 110 to connect these components.

In some embodiments, bar 110 and baffle 112 provide reinforcement and strength to frame 102. For example, bar 110 and baffle 112 may be located in the middle of frame 102 to provide strength to frame 102, prevent deformation of frame 102, and/or improve frame 102 bottom flatness. This can facilitate insertion of frame 102 into a bay of a chassis. The middle of frame 102 can be vulnerable to deformation due to the weight of components such as processor heatsinks 108, board 104, and memory modules 106. Baffle 112 may provide additional stability and/or rigidness to frame 102 so that frame 102 may be assisted in sustaining the weight of components on board 104. Bar 110 and baffle 112 may be made of any material that provides additional strength to frame 102 to prevent deformation. For example, bar 110 and baffle 112 may both be made of metal. As another example, bar 110 may be made of metal while baffle 112 is made of another material, such as a strong plastic (e.g., nylon, PVC, or polycarbonate). As another example, the bar may be made of a strong plastic (e.g., nylon, PVC, or polycarbonate).

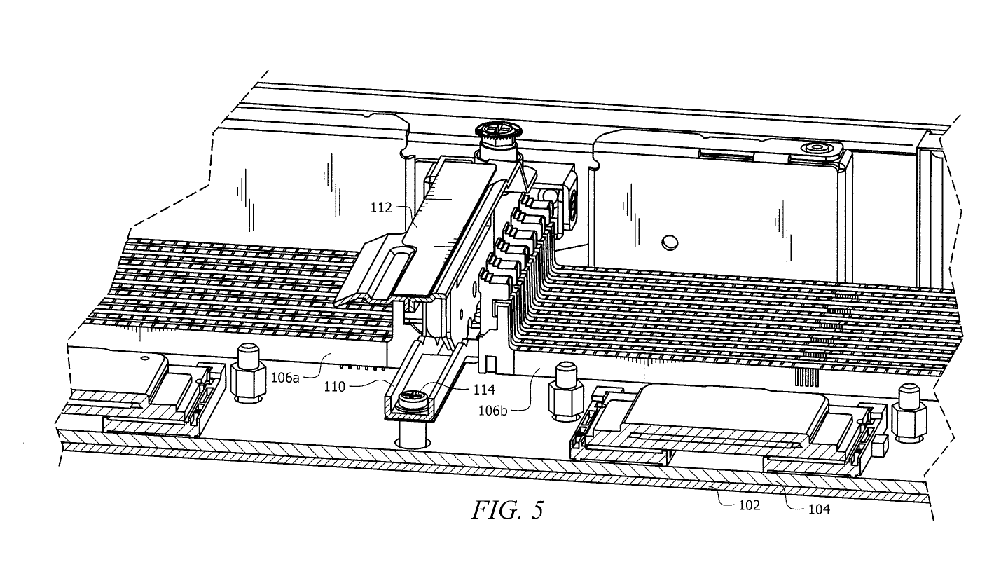

In certain embodiments, bar 110 is connected to frame 102 through board 104. As shown in FIG. 1A, board 104 may comprise a plurality of holes. At least a portion of these holes allow fasteners (e.g., screws) to fix portions (e.g., substantially straight or planar portions) of bar 110 to frame 102 through board 104. An example of this is shown in FIG. 5, which depicts fastener 114 (e.g., a screw) engaging with bar 104, going through a hole on board 104, and engaging with frame 102 in order to connect bar 104 to frame 102. A plurality of fasteners 114 may be used along the length of bar 110 to secure bar 110 to frame 104.

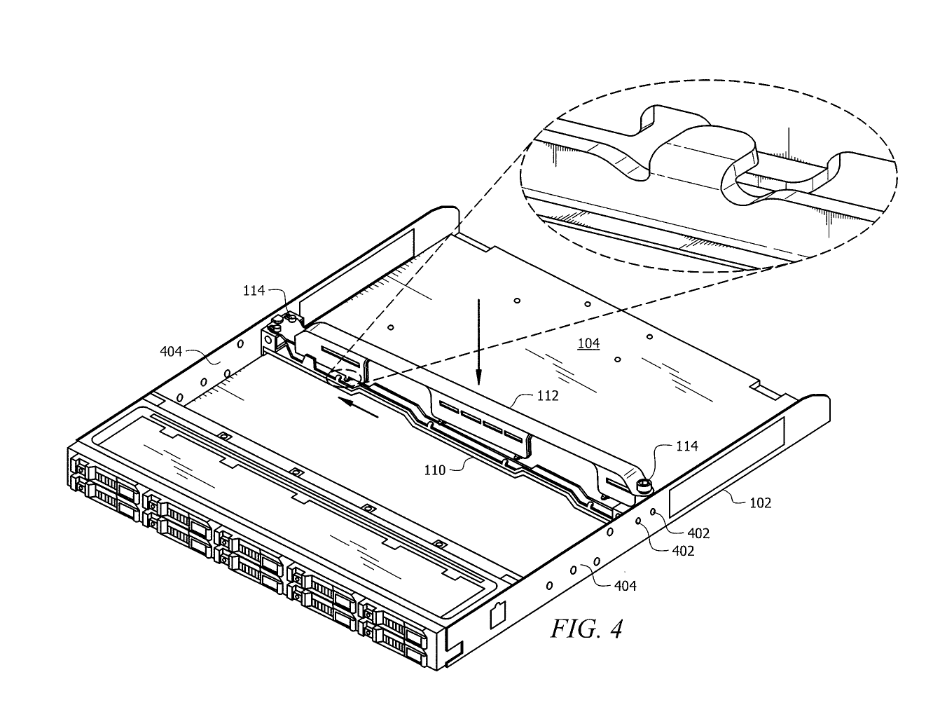

Bar 110 may be connected to one or more side walls of frame 102 in some embodiments. This connection may be made instead of, or in addition to, connecting bar 110 to frame 102 through board 104. As depicted in FIG. 4, frame 102 includes two side walls 404 that each include a plurality of holes 402. When connecting bar 110 to frame 102, one or more fasteners 114 may be used to connect the side of bar 110 to one side wall 404 of frame 102. Connecting bar 110 to one or more side walls 404 of frame 102 can improve the connection between bar 110 and frame 102. Connecting bar 110 to one or more side walls 404 of frame 102 can provide additional strength to frame 102, which can help reduce or prevent deformation.

In some embodiments, baffle 112 may be connected to bar 110. For example, once bar 110 is secured to frame 102 and, in some embodiments, connected to one or more side walls of frame 102, baffle 112 may be inserted. In some embodiments, baffle 112 and bar 110 as connected may form a structure similar to an I-beam. As shown in the embodiment depicted in FIG. 5, baffle 112 and bar 110 may each include a set of protruding tabs, which engage when aligned. For example, as indicated by the arrows in FIG. 4, baffle 112 may be placed over bar 110 and slid to the left such that the protruding tabs of baffle 112 and the protruding tabs of bar 110 align and engage. The engagement of the tabs can prevent (or reduce the chances of) baffle 112 from moving; this can facilitate baffle 112 providing stiffness and/or strength to frame 102. Once the sets of protruding tabs are engaged, in some embodiments, an additional connection between bar 110 and baffle 112 may be established using fasteners 114. For example, fasteners 114 may include thumb screws, hook and slot features, additional tabs, or any component that further engages the connection between bar 110 and baffle 112.

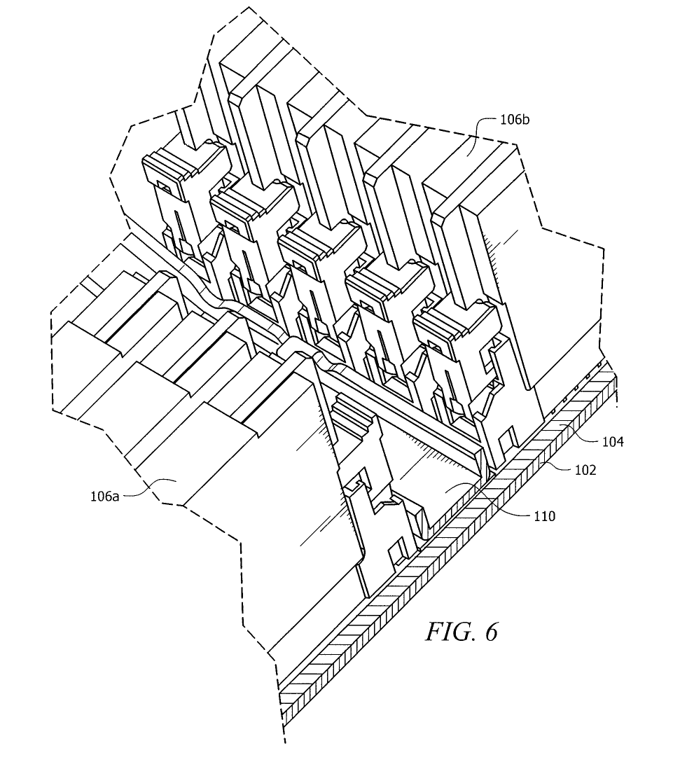

Baffle 112, in some embodiments, may be removed and disconnected from bar 110. With reference to the example shown in FIG. 4, fastener 114 (e.g., a thumb screw) may be undone using a tool-less procedure, such as a user unscrewing the thumb screw by hand , or any method suitable to remove any connections or fasteners. Continuing the example, baffle 112 may be slid to the right (e.g., away from fastener 114) to remove the engagement between the sets of protruding tabs, and baffle 114 may be lifted away from bar 110. An example of system 100 with baffle 112 removed is depicted in FIG. 6 using a cross-sectional view. In some embodiments, an advantage of being able to remove baffle 112 is being able to access one or more memory modules 106 for installation and/or replacement using some or no tools. In some frames 102, there can be limited space between the front and rear rows of memory modules 106. FIG. 5 and FIG. 6 show an example of limited space between front rows 106a and rear rows 106b of memory modules 106. Dividing the reinforcement structure of frame 102 into two pieces, bar 110 and baffle 112, as shown in FIG. 1A, can provide access to memory modules 106 (e.g., access to a socket latch) for maintenance or replacement by removing baffle 112, while allowing bar 110 to remain securely connected to frame 102. Being able to remove baffle 112, in some embodiments, increases accessibility to memory modules 106 while still allowing for strengthening frame 102 in such high density environments.

In some embodiments, baffle 112 may include first set of openings 304 and second set of openings 302, as shown in FIG. 3A and FIG. 3B. Each of first set of openings 304 may be larger than each of second set of openings 302, such that first set of openings 304 are configured to direct air to processor heatsinks 108 and second set of openings 302 are configured to direct air to memory modules 106. Because the processors associated with processor heatsinks 108 may generate more heat than memory modules 106, processors may require more cooling than memory modules 106. Thus, having a larger opening near processor heatsinks 108 allows for more air flow and downstream cooling, helping to cool the processors, facilitate continued operation, and reducing the chance of or preventing overheating. In some embodiments, the size of the openings may match or correspond to the sizes of processor heatsinks 108 to ensure air flow reaches processor heatsinks 108 to prevent (or reduce the chance of) overheating. For example, the width of the first set of openings 304 may vary depending on the size of processor heatsink 108 being used to cool the processor. Examples of baffle 112 are shown in FIG. 3A and FIG. 3B. As shown in FIG. 3A and FIG. 3B, baffle 112 may include any suitable number of openings. By varying the size and number of the openings, baffle 112 may include structure and material to strengthen frame 102, while providing openings to provide cooling air to components on board 104.

Modifications, additions, or omissions may be made to the systems described herein without departing from the scope of the disclosure. For example, information handling system 100 may include any number of memory modules 106 and processor heatsinks 108. The components may be integrated or separated. Moreover, the operations may be performed by more, fewer, or other components. Additionally, the operations may be performed using any suitable logic comprising software, hardware, and/or other logic.

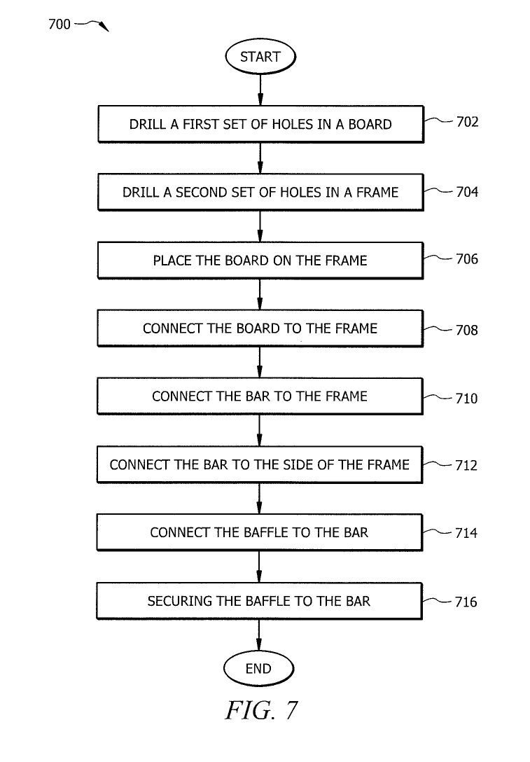

FIG. 7 is a flowchart of an example of connecting baffle 112 and bar 110 to information handling system 100. The method begins at step 702, with drilling a first set of holes in board 104. At step 704, in some embodiments, a second set of holes are drilled into frame 102. Each set of holes may include any number of holes. In some embodiments, the first set of holes may include the same number of holes as the second set of holes. In some embodiments, the first set of holes and second set of holes may be the same size such that each hole may completely overlap with a hole from the other set of holes.

At step 706, in some embodiments, board 104 is placed on frame 102. As an example, the first set of holes on board 104 may align with the second set of holes on frame 102. At step 708, in some embodiments, board 104 is connected to frame 102. Fasteners may be arranged through the first set of holes in board 104 and the second set of holes in frame 102. Board 104 may be connected to frame 102 using screws, bolts, buckles, solder, buttons, or any suitable fastener to connect these components.

In some embodiments, at step 710, bar 110 is connected to frame 102. Bar 110, in some embodiments, may include a plurality of holes that align with the first set of holes on board 104 and the second set of holes in frame 102. At least a portion of these holes allow fasteners (e.g., screws) to fix one or more portions of bar 110 to frame 102 through board 104. A fastener (e.g., screw) may engage with the top side of bar 104, go through a hole on board 104, and engage with frame 102, in order to connect bar 104 to frame 102. A plurality of fasteners may be used along the length of bar 110 to secure bar 110 to frame 104. In some embodiments, step 708, described above, may be omitted if frame 102 and board 104 need not be separately connected. For example, frame 102 and board 104 may be connected at step 710 by bar 110 being connected to frame 102 through board 104.

Bar 110 may be connected to the side wall of frame 102 at step 712, in some embodiments. For example, frame 102 may include one or more side walls with a plurality of holes. When connecting bar 110 to frame 102, one or more fasteners 114 may be used to connect the side of bar 110 to one side wall of frame 102. Connecting bar 110 to one or more side walls 404 of frame 102 can allow for a more secure connection and/or provide additional strength and rigidness to frame 102 to prevent or reduce deformation.

At step 714, in some embodiments, baffle 112 is connected to bar 110. Baffle and bar 110 may be connected using nails, screws, solder, glue, fasteners, or any suitable connection mechanism. In some embodiments, baffle 112 and bar 110 may be connected through sets of protruding tabs. For example, baffle 112 and bar 110 may each include a set of protruding tabs, which engage when aligned. Continuing the example, baffle 112 may be placed on top of bar 110 and slid in such that the protruding tabs of baffle 112 and protruding tabs of bar 110 align and engage. The engagement of the tabs can help reduce or prevent baffle 112 from moving. The engagement can allow baffle 112 to provide stiffness and/or strength to frame 102.

Baffle 112 may be secured to bar 110 at step 716, in some embodiments. If further securing is required or preferred after connecting baffle 112 and bar 110 in step 714 above, the method may include additional connections. In some embodiments, fasteners may contribute to an additional connection between bar 110 and baffle 112. For example, fasteners may include thumb screws, hook and slot engagements, additional tabs locking baffle 112 into place, or any component that further engages the connection between bar 110 and baffle 112. After step 714, the method ends.

Modifications, additions, or omissions may be made to the methods described herein without departing from the scope of the disclosure. The steps may be combined, modified, or deleted where appropriate, and additional steps may be added. For example, step 716 of securing baffle 112 to bar 110 may be omitted if the connection created in step 714 does not require additional security. As an additional example, step 712 of connecting bar 110 to a side wall of frame 102 may not be necessary in order to securely connect bar 110 to frame 102. Additionally, the steps may be performed in any suitable order without departing from the scope of the present disclosure.

Although the present invention has been described with several embodiments, a myriad of changes, variations, alterations, transformations, and modifications may be suggested to one skilled in the art, and it is intended that the present invention encompass such changes, variations, alterations, transformations, and modifications as fall within the scope of the appended claims.

1. A system comprising:
a bar connected to a frame through a plurality of holes in a board; and
a baffle connected to the bar, the baffle configured to direct air to components on the board.

2. The system of claim 1, further comprising:
one or more fasteners to connect the bar and the baffle;
one or more screws arranged through the plurality of holes in the board to connect the bar to the frame;
wherein the bar comprises a first set of tabs;
wherein the baffle comprises a second set of tabs, the second set of tabs configured to interlock with the first set of tabs;
wherein the bar and the baffle comprise metal;
wherein the baffle comprises a first set of openings and a second set of openings, each opening of the first set of openings being larger than each opening of the second set of openings, the first set of openings configured to direct air to a processor and the second of openings configured to direct air to a memory module;
wherein the bar is substantially straight; and
wherein the bar comprises a second portion, the second portion connected to the frame and not connected to the board.

3. The system of claim 1, further comprising one or more fasteners to connect the bar and the baffle.

4. The system of claim 1, wherein the baffle comprises a first set of openings and a second set of openings, each opening of the first set of openings being larger than each opening of the second set of openings, the first set of openings configured to direct air to a processor and the second of openings configured to direct air to a memory module.

5. The system of claim 1, further comprising one or more screws arranged through the plurality of holes in the board to connect the bar to the frame.

6. The system of claim 1, wherein:
the bar comprises a first set of tabs; and
the baffle comprises a second set of tabs, the second set of tabs configured to interlock with the first set of tabs.

7. The system of claim 1, wherein the bar and the baffle comprise metal.

8. The system of claim 1, wherein the bar comprises metal and the baffle comprises plastic.

9. The system of claim 1, wherein the bar is substantially straight.

10. The system of claim 1, wherein the bar comprises a second portion, the second portion connected to the frame and not connected to the board.

11. A method, comprising:
connecting a bar and a baffle, the baffle configured to direct air to components on a board.

12. The method of claim 11, further comprising:
drilling a first set of holes in a board;
drilling a second set of holes in a frame;
placing the board on the frame, the first set of holes aligning with the second set of holes;
connecting the board to the frame;
connecting the bar to the frame through the first set of holes in the board using one or more screws arranged through the first set of holes and the second set of holes;
wherein connecting the bar and the baffle comprises using one or more fasteners;
wherein the bar comprises a first set of tabs;
wherein the baffle comprises a second set of tabs, the second set of tabs configured to interlock with the first set of tabs;
wherein the bar and the baffle comprise metal;
wherein the baffle comprises a first set of openings and a second set of openings, each opening of the first set of openings being larger than each opening of the second set of openings, the first set of openings configured to direct air to a processor and the second of openings configured to direct air to a memory module;
wherein the bar is substantially straight; and
wherein the bar comprises a second portion, the second portion connected to the frame and not connected to the board.

13. The method of claim 11, further comprising:
drilling a first set of holes in a board;
drilling a second set of holes in a frame;
placing the board on the frame, the first set of holes aligning with the second set of holes;
connecting the board to the frame; and
connecting the bar to the frame through the first set of holes in the board using one or more screws arranged through the first set of holes and the second set of holes.

14. The method of claim 1, wherein connecting the bar and the baffle comprises using one or more fasteners.

15. The method of claim 1, wherein the baffle comprises a first set of openings and a second set of openings, each opening of the first set of openings being larger than each opening of the second set of openings, the first set of openings configured to direct air to a processor and the second of openings configured to direct air to a memory module.

16. The method of claim 1, further comprising connecting the bar to the frame through the first set of holes in the board using one or more screws arranged through the first set of holes and the second set of holes.

17. The method of claim 1, wherein:
the bar comprises a first set of tabs; and
the baffle comprises a second set of tabs, the second set of tabs configured to interlock with the first set of tabs.

18. The method of claim 1, wherein the bar and the baffle comprise metal.

19. The method of claim 1, wherein the bar is substantially straight.

20. The method of claim 1, wherein the bar comprises a second portion, the second portion connected to the frame and not connected to the board.
